(19) United States
(12) Patent Application Publication
(10) Pub. No.: US 2009/0278603 A1
(43) Pub. Date: Nov. 12, 2009

(54) ALL N-TYPE TRANSISTOR HIGH-SIDE CURRENT MIRROR

(75) Inventors: Giuseppe Grillo, Eindhoven (NL); Mihai Adrian Tiberiu Sanduleanu, Maastricht (NL); Johannes Hubertus Antonius Brekelmans, Nederweert (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/577,308

(22) PCT Filed: Oct. 13, 2005
(86) PCT No.: PCT/IB05/53370

§ 371 Date: Jul. 7, 2009

Related U.S. Application Data
(60) Provisional application No. 60/618,564, filed on Oct. 15, 2004.

(51) Int. Cl. H03F 3/04; H03F 3/45

(52) U.S. Cl. 330/257; 330/288

(57) ABSTRACT

The present invention relates to an all n-type transistor current mirror for mirroring an input current to an output current. The current mirror comprises an input n-type transistor (T4, QO, T1) interposed between a positive supply plane (VCC) and an input node (104, 202, 310) with its collector being connected to the positive supply plane (VCC) and its emitter being connected to the input node (104, 202, 310). An output n-type transistor (T3, Q1, T2) is interposed between the positive supply plane (VCC) and an output node (106, 204, 314) with its collector being connected to the positive supply plane (VCC) and its emitter being connected to the output node (106, 204, 314). A feedback circuit equals base-emitter voltages of the input (T4, QO, T1) and the output transistor (T3, Q1, T2) in order to mirror the emitter current of the input transistor (T4, QO, T1) to the emitter current of the output transistor (T3, Q1, T2). The all n-type transistor current mirror is highly advantageous by overcoming the shortcomings of technologies such as MOBI3, GaAs, and InP of being unable to provide p-type transistors.

This invention relates to current mirrors used in integrated circuits and in particular to a high-side mirror using only n-type transistors.

Current mirrors are very well known circuits, widely used in integrated electronic circuits. Improvements in performance of current mirrors resulted in the creation of a wide variety of different implementations, the most common being biasing circuits and current amplifiers.

In general terms, current mirrors are circuits having an input side—input mirror—in communication with an input current source and an output side—output mirror—to which the input current is mirrored.

State of the art current mirrors employ, in general, pairs of similar transistors. The low-side mirrors are generally implemented using n-type transistors such as npn and NMOS and mirror currents with respect to ground. The high-side mirrors are generally implemented using p-type transistors such as pnp and PMOS and mirror currents with respect to a positive supply plane.

However, in several state of the art integrated circuit manufacturing processes p-type transistors are not available. For example, in GaAs HBT processes and in InP HBT processes it is not possible to manufacture high-side mirrors using p-type transistors.

Based upon the foregoing, there is a need to enable manufacturing of this basic circuit that is employed in a wide range of technologies using processes that have no p-type transistors available. Therefore, it would be advantageous to provide high-side mirrors using only n-type transistors.

It is, therefore, an object of the invention to provide a high side mirror using only n-type transistors.

In accordance with the present invention there is provided a n-type transistor current mirror for mirroring an input current I_in to an output current I_out comprising: an input node for receiving the input current I_in; an output node for providing the output current I_out; an input n-type transistor interposed between a positive supply plane and the input node with its collector being connected to the positive supply plane and its emitter being connected to the input node; an output n-type transistor interposed between the positive supply plane and the output node with its collector being connected to the positive supply plane and its emitter being connected to the output node; and, a feedback circuit interposed between the input node and the output node, the feedback circuit being in communication with a link connecting the base of the input transistor with the base of the high side transistor, the feedback circuit for maintaining base-emitter voltages of the input and the output transistor equal in order to mirror the emitter current of the input transistor to the emitter current of the output transistor.

In accordance with an aspect of the present invention there is provided a storage medium having data stored therein, the data for when executed resulting in an integrated circuit design of a n-type transistor current mirror for mirroring an input current I_in to an output current I_out comprising: an input node for receiving the input current I_in; an output node for providing the output current I_out; an input n-type transistor interposed between a positive supply plane and the input node with its collector being connected to the positive supply plane and its emitter being connected to the input node; an output n-type transistor interposed between the positive supply plane and the output node with its collector being connected to the positive supply plane and its emitter being connected to the output node; and, a feedback circuit interposed between the input node and the output node, the feedback circuit being in communication with a link connecting the base of the input transistor with the base of the high side transistor, the feedback circuit for maintaining base-emitter voltages of the input and the output transistor equal in order to mirror the emitter current of the input transistor to the emitter current of the output transistor.

In accordance with the present invention there is further provided a method for mirroring an input current I_in to an output current I_out comprising: providing an input node for receiving the input current I_in; providing an output node for providing the output current I_out; providing an input n-type transistor interposed between a positive supply plane and the input node with its collector being connected to the positive supply plane and its emitter being connected to the input node; providing an output n-type transistor interposed between the positive supply plane and the output node with its collector being connected to the positive supply plane and its emitter being connected to the output node; providing a feedback circuit interposed between the input node and the output node, the feedback circuit being in communication with a link connecting the base of the input transistor with the base of the high side transistor; and, mirroring the emitter current of the input transistor to the emitter current of the output transistor by maintaining base-emitter voltages of the input and the output transistor equal using the feedback circuit.

In accordance with the present invention there is further provided a current mirror for mirroring an input current I_in to an output current I_out comprising: an input node for receiving the input current I_in; an output node for providing the output current I_out; an input resistor interposed between a positive supply plane and the input node; an output resistor interposed between the positive supply plane and the output node; and, a feedback circuit interposed between the input node and the output node, the feedback circuit for maintaining voltage drops across the input and the output resistors equal in order to mirror the input current to the output current.

In accordance with an aspect of the present invention there is provided a storage medium having data stored therein, the data for when executed resulting in an integrated circuit design of a current mirror for mirroring an input current I_in to an output current I_out comprising: an input node for receiving the input current I_in; an output node for providing the output current I_out; an input resistor interposed between a positive supply plane and the input node; an output resistor interposed between the positive supply plane and the output node; and, a feedback circuit interposed between the input node and the output node, the feedback circuit for maintaining voltage drops across the input and the output resistors equal in order to mirror the input current to the output current.

In accordance with the present invention there is further provided a method for mirroring an input current I_in to an output current I_out comprising: providing an input node for receiving the input current I_in; providing an output node for providing the output current I_out; providing an input resistor interposed between a positive supply plane and the input node; providing an output resistor interposed between the positive supply plane and the output node; providing a feedback circuit interposed between the input node and the output node; and, mirroring the input current to the output current by maintaining voltage drops across the input and the output resistors equal using the feedback circuit.

Exemplary embodiments of the invention will now be described in conjunction with the following drawings, in which:

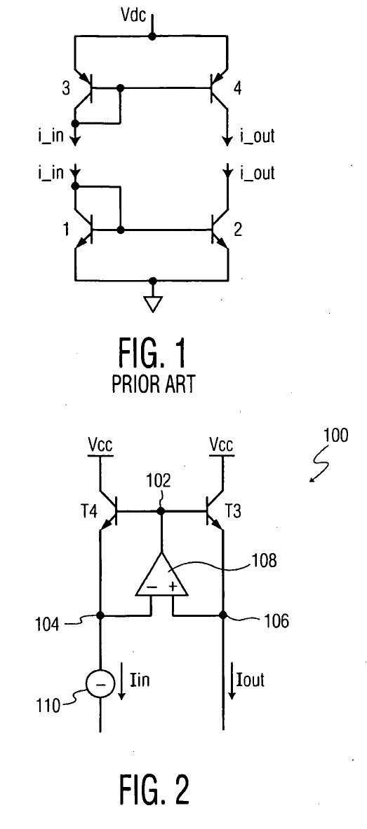

FIG. 1 is a simplified circuit diagram schematically illustrating a prior art current mirror;

FIG. 2 is a simplified circuit diagram schematically illustrating a first embodiment of an all n-type transistor current mirror;

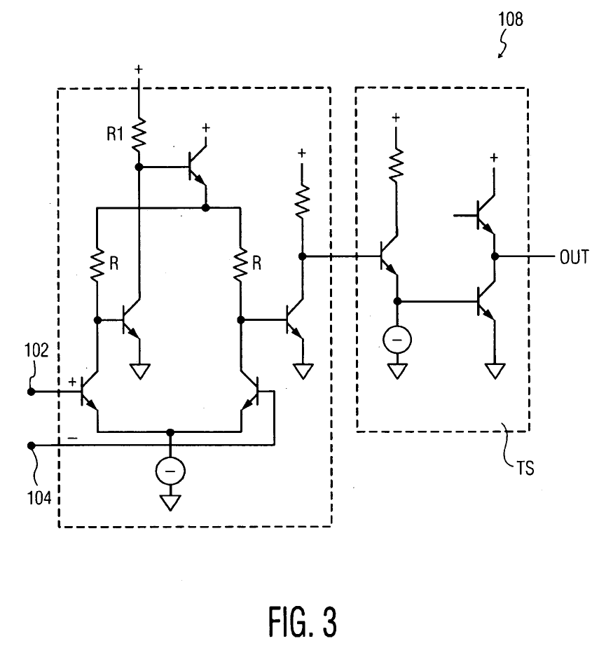

FIG. 3 is a simplified circuit diagram of a feedback amplifiers for use in the all n-type transistor current mirror;

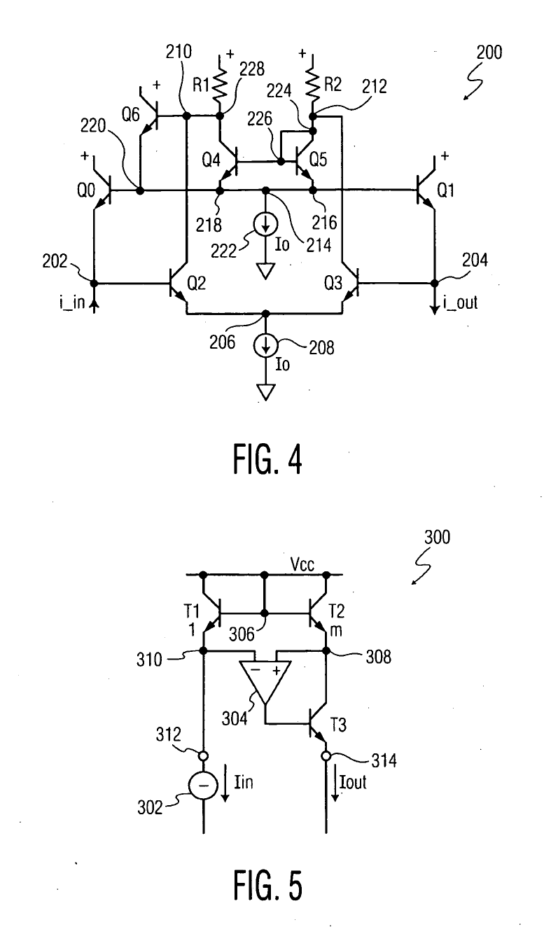

FIG. 4 is a simplified circuit diagram schematically illustrating a second embodiment of a all n-type transistor current mirror;

FIG. 5 is a simplified circuit diagram schematically illustrating a third embodiment of a all n-type transistor current mirror;

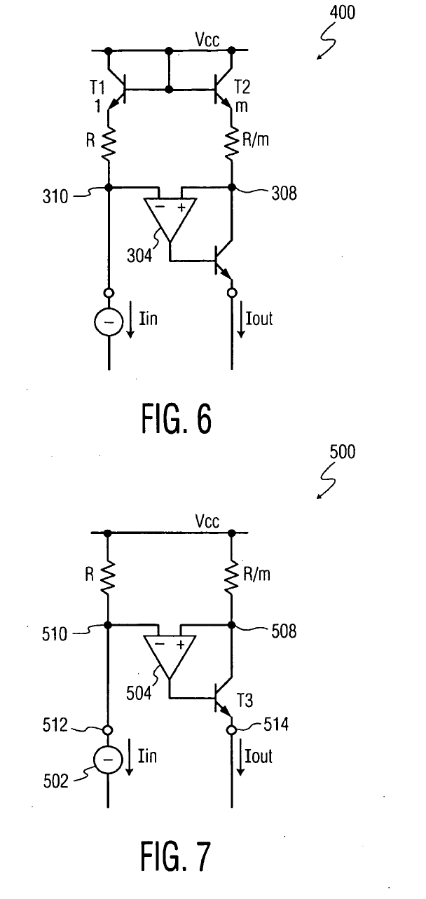

FIG. 6 is simplified circuit diagram schematically illustrating a fourth embodiment of a all n-type transistor current mirror;

FIG. 7 is simplified circuit diagram schematically illustrating a fifth embodiment of a all n-type transistor current mirror;

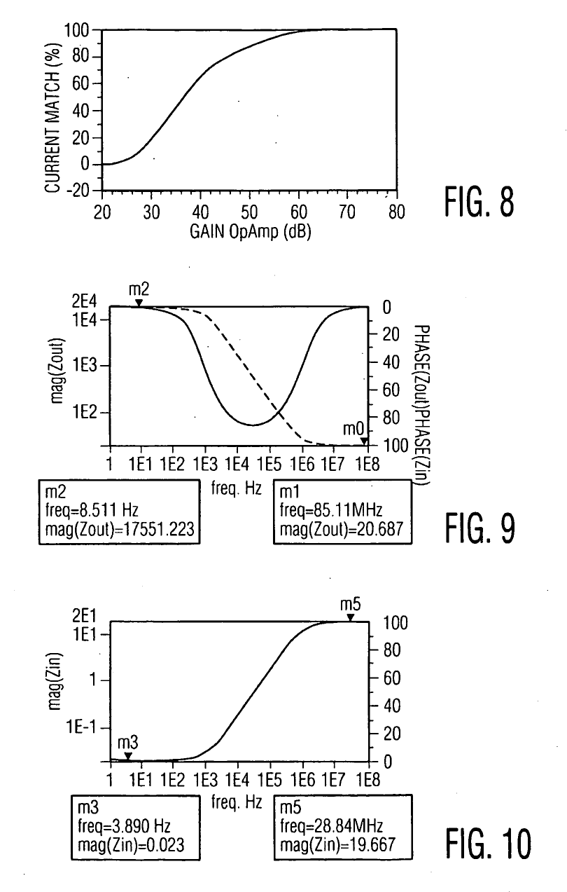

FIG. 8 is a simplified diagram illustrating current matching of the first embodiment;

FIG. 9 is a simplified diagram illustrating output impedance as function of frequency of the first embodiment; and,

FIG. 10 is a simplified diagram illustrating output impedance as function of frequency of the first embodiment.

In the following description the various embodiments of the invention will be illustrated using npn transistors. As will become evident to those of skill in the art, the circuits are extendable to other kinds of n-type transistors such as, for example, NMOS transistors. For simplicity, the expressions “base, collector, and emitter” are used in the following description. As is evident to those skilled in the art, these expressions are easily substituted with the expressions “gate, drain, and source”, respectively, when referring to FET devices like NMOS transistors.

Referring to FIG. 1, a basic circuit of a prior art current mirror is shown. The low-side mirror is implemented using n-type transistors 1 and 2 such as npn and NMOS and mirrors currents i_in with respect to ground or a negative supply plane. The high-side mirror is implemented using p-type transistors 3 and 4 such as pnp and PMOS and mirrors currents i_out with respect to a positive supply plane Vdc.

Referring to FIG. 2, a first embodiment of a current mirror 100 according to the invention is shown. Current source 110 represents the current Iin that is mirrored to Iout. The current source 110 is connected to the emitter of n-type transistor T4. The collectors of transistors T3 and T4 are each connected to the positive supply plane VCC, while the bases of the transistors T3 and T4 are connected to each other. The current mirror 100 further comprises a feedback amplifier 108 such as an Op-Amp. The positive input of the feedback amplifier 108 is connected to the emitter of the transistor T3 via node 106, while the negative input of the feedback amplifier 108 is connected to node 104 interposed between the current source 110 and the emitter of the transistor T4. The output of the feedback amplifier 108 is connected to node 102 interposed between the bases of transistors T3 and T4. In operation, the feedback forces the transistors T3 and T4 to have the same base-emitter voltage Vbe, therefore, forcing the emitter currents of the transistors T3 and T4 to be equal or, alternatively, proportionally related to each other depending on a scaling factor defined by the emitter area of transistors T3 and T4. In case the current on transistor T3 increases, the voltage at the negative input of the feedback amplifier 108 increases and, therefore, the base voltage of the transistors T3 and T4 decreases, decreasing the voltage at the emitter of transistor T3. The feedback amplifier 108 is designed such that operation of the circuit in a predetermined operational frequency range is stable and that not too much energy is dissipated. A possible design for a feedback amplifier 108 is shown in FIG. 3. Alternatively, the “totem-pole” output stage TS, shown in FIG. 3, is substituted with another type of output stage or omitted.

Referring to FIG. 4, a second embodiment 200 of a current mirror according to the invention using only n-type transistors is shown. Here, current i_in at node 202—input—is mirrored to i_out at node 204—output—via n-type transistors Q0 and Q1. In this current mirror the base-emitter voltage Vbe of the transistors Q0 and Q1 is kept constant by employing n-type transistors Q2, Q3, Q4, Q5, and Q6, forcing the emitter currents of the transistors Q0 and Q1 to be equal or, alternatively, proportionally related to each other. The collectors of the transistors Q0 and Q1 are connected to the positive supply plane. To provide feedback the emitter of transistor Q1 is connected to the base of n-type transistor Q3, as well as the emitter of Q0 to the base of n-type transistor Q2. The emitters of the transistors Q2 and Q3 are connected to each other and via node 206 and current source 208 to ground or, alternatively, to a negative supply plane. The collectors of the transistors Q2 and Q3 are connected to a positive supply plane via node 210 and resistor R1, and node 212 and resistor R2, respectively. The bases of the transistors Q0 and Q1 are connected to each other and to the feedback circuit via nodes 214, 216, 218, and 220. The node 214 connects the feedback circuit to ground or, alternatively, to a negative supply plane via current source 222. The nodes 216 and 218 connect the bases of the transistors Q0 and Q1 to the emitters of the transistors Q4 and Q5, respectively. The bases of the transistors Q4 and Q5 are connected to each other, while the collectors are connected to the positive supply plane via the resistors R1 and R2, respectively. A feedback loop between nodes 224 and 226 connects the collector and the base of the transistor Q5. The transistor Q6 is interposed between the bases of the transistors Q0 and Q1, and the positive supply plane via the resistor R1, with the emitter being connected to the node 220, the collector being connected to the positive supply plane, and the base being connected to node 228 interposed between the collector of the transistor Q4 and the resistor R1.

In the first and the second embodiment of the invention the output DC voltage of the current mirror is equal to the input DC voltage. This is undesirable in some applications. Namely, an ideal current mirror has a fixed input voltage, and its output current is independent from the output voltage. Moreover, its output DC voltage is independent from the mirror itself and determined by the load. This independence from the output voltage is achieved in the embodiments described below.

Referring to FIG. 5, a third embodiment 300 of a current mirror using only n-type transistors according to the invention is shown. Current Iin—current source 302 connected to input node 312—is mirrored to Iout at output node 314 via n-type transistors T1 and T2. The base-emitter voltage Vbe of the transistors T1 and T2 is kept equal by feedback amplifier 304 with the positive input connected to the high side via node 308, the negative input connected to the low side via node 310, and the output connected to the base of transistor T3 interposed in the high side. Further, the bases of the transistors T1 and T2 are connected to each other and the positive supply plane VCC via node 306. The collectors of the transistors T1 and T2 are connected to the positive supply plane VCC. The gain of the feedback amplifier 304 sets the base-emitter voltage Vbe of the transistors T1 and T2 equal as in the first and second embodiment. However, the additional transistor T3 makes the DC voltage at the output node 314 independent from the DC voltage at the input node 312.

Referring to FIG. 6, a fourth embodiment 400 of a current mirror using only n-type transistors according to the invention is shown. The circuitry of this embodiment is substantially the same as the third embodiment, but having resistors R and R/m interposed between the emitters of the transistors T1 and T2, and the nodes 308 and 310, respectively. Interposing the resistors enhances the precision to which the output current matches the input current, thus relaxing the requirements of the feedback amplifier 304. Alternatively, the resistors are connected to the bases of the transistors T1 and T2 instead of the emitters. Optionally, resistors are connected to the emitters as well as to the bases of the transistors T1 and T2.

Referring to FIG. 7, a fifth embodiment 500 of a current mirror using only n-type transistors according to the invention is shown. Current Iin—current source 502 connected to input node 512—is mirrored to lout at output node 514 via resistors R and R/m. The voltage drop across the resistors R and R/m is kept equal by feedback amplifier 504 with the positive input connected to the high side via node 508, the negative input connected to the low side via node 510, and the output connected to the base of n-type transistor T3 interposed in the high side. Again, the transistor T3 makes the DC voltage at the output node 514 independent from the DC voltage at the input node 512. Here, the mirroring is not achieved by equaling base-emitter voltages, but by equaling the voltage drop across two resistances.

In a current mirror it is desired to have low input impedance and high output impedance. Whilst in the above embodiments the input impedance tends to be low as desired, since it is equal to the emitter impedance of the common-collector, the output impedance tends to be low as well. The loop gain of the feedback circuit raises the output impedance to a desired level as shown in equation (1):

$${Z}_{0} = \frac{1}{gm} ( 1 + A ) \qquad ( 1 )$$

where A is the loop gain. It is noted that in order to reach the level of impedance equal to r0, the loop gain is in the order of A=gm r0=VA/VT where VA is the Early voltage and VT is the thermal voltage.

FIGS. 8 to 10 illustrate simulation results for the first embodiment of the invention. In FIG. 8 the ratio between input current and output current is shown. The transistors are npn InP SHBT, from GCS, biased at 3 mA each. A gain of 60 dB (1000) gives a matching of approximately 95%. In FIG. 9 the output impedance of the current mirror as in the first embodiment is presented. The feedback amplifier has a voltage gain of 60 dB and a bandwidth of 1 MHz and its output impedance is 100.In FIG. 10 the input impedance of the current mirror is shown. At frequencies higher than the amplifier bandwidth (1 MHz), the input impedance is equal to 1/gm. This value is divided by the amplifier gain at lower frequencies.

The current mirrors with only n-type transistors according to the invention are highly advantageous by overcoming the shortcomings of technologies such as MOBI3, GaAs, and InP of being unable to provide p-type transistors.

Numerous other embodiments of the invention will be apparent to persons skilled in the art without departing from the spirit and scope of the invention as defined in the appended claims.

1-15. (canceled)

16. An n-type transistor current mirror for mirroring an input current I_in to an output current I_out comprising:
an input node for receiving the input current I_in;
an output node for providing the output current I_out;
an input n-type transistor interposed between a positive supply plane and the input node with its collector being connected to the positive supply plane and its emitter being connected to the input node;
an output n-type transistor interposed between the positive supply plane and the output node with its collector being connected to the positive supply plane and its emitter being connected to the output node; and,
a feedback circuit interposed between the input node and the output node, the feedback circuit being in communication with a link connecting the base of the input transistor with the base of the high side transistor, the feedback circuit for maintaining base-emitter voltages of the input and the output transistor equal in order to mirror the emitter current of the input transistor to the emitter current of the output transistor.

17. An n-type transistor current mirror for mirroring an input current I_in to an output current I_out as defined in claim 16 wherein the feedback circuit comprises an operational amplifier.

18. An n-type transistor current mirror for mirroring an input current I_in to an output current I_out as defined in claim 16 wherein the output node has a predetermined impedance.

19. An n-type transistor current mirror for mirroring an input current I_in to an output current I_out as defined in claim 17 wherein the output node has a predetermined impedance.

20. An n-type transistor current mirror for mirroring an input current I_in to an output current I_out as defined in claim 3 wherein the feedback circuit is dimensioned such that a loop gain of the feedback circuit is sufficient for providing the predetermined impedance.

21. An n-type transistor current mirror for mirroring an input current I_in to an output current I_out as defined in claim 17 wherein the operational amplifier is connected such that its positive input is connected to the output node, its negative input is connected to the input node, and its output is in communication with the link connecting the base of the input transistor with the base of the high side transistor.

22. An n-type transistor current mirror for mirroring an input current I_in to an output current I_out as defined in claim 17 wherein the operational amplifier is connected such that its positive input is connected to the output node, its negative input is connected to the input node, and its output is in communication with a base of a n-type feedback transistor interposed between the emitter of the output transistor and the output node.

23. An n-type transistor current mirror for mirroring an input current I_in to an output current I_out as defined in claim 22 wherein the link connecting the base of the input transistor with the base of the high side transistor is connected to the positive supply plane.

24. An n-type transistor current mirror for mirroring an input current I_in to an output current I_out as defined in claim 23 comprising:
an input resistor interposed between the emitter of the input transistor and the feedback amplifier; and,
an output resistor interposed between the emitter of the output transistor and the feedback amplifier.

25. An storage medium having data stored therein, the data for when executed resulting in an integrated circuit design of a n-type transistor current mirror for mirroring an input current I_in to an output current I_out comprising:
an input node for receiving the input current I_in;
an output node for providing the output current I_out;
an input n-type transistor interposed between a positive supply plane and the input node with its collector being connected to the positive supply plane and its emitter being connected to the input node;
an output n-type transistor interposed between the positive supply plane and the output node with its collector being connected to the positive supply plane and its emitter being connected to the output node; and,
a feedback circuit interposed between the input node and the output node, the feedback circuit being in communication with a link connecting the base of the input transistor with the base of the high side transistor, the feedback circuit for maintaining base-emitter voltages of the input and the output transistor equal in order to mirror the emitter current of the input transistor to the emitter current of the output transistor.

26. An method for mirroring an input current I_in to an output current I_out comprising:
providing an input node for receiving the input current I_in;
providing an output node for providing the output current I_out;
providing an input n-type transistor interposed between a positive supply plane and the input node with its collector being connected to the positive supply plane and its emitter being connected to the input node;
providing an output n-type transistor interposed between the positive supply plane and the output node with its collector being connected to the positive supply plane and its emitter being connected to the output node;
providing a feedback circuit interposed between the input node and the output node, the feedback circuit being in communication with a link connecting the base of the input transistor with the base of the high side transistor; and,
mirroring the emitter current of the input transistor to the emitter current of the output transistor by maintaining base-emitter voltages of the input and the output transistor equal using the feedback circuit.

27. An current mirror for mirroring an input current I_in to an output current I_out comprising:
an input node for receiving the input current I_in;
an output node for providing the output current I_out;
an input resistor interposed between a positive supply plane and the input node;
an output resistor interposed between the positive supply plane and the output node; and,
a feedback circuit interposed between the input node and the output node, the feedback circuit for maintaining voltage drops across the input and the output resistors equal in order to mirror the input current to the output current.

28. An current mirror for mirroring an input current I_in to an output current I_out as defined in claim 27 wherein the output node has a predetermined impedance.

29. An current mirror for mirroring an input current I_in to an output current I_out as defined in claim 28 wherein the feedback circuit is dimensioned such that a loop gain of the feedback circuit is sufficient for providing the predetermined impedance.

30. An storage medium having data stored therein, the data for when executed resulting in an integrated circuit design of a current mirror for mirroring an input current I_in to an output current I_out comprising:
an input node for receiving the input current I_in;
an output node for providing the output current I_out;
an input resistor interposed between a positive supply plane and the input node;
an output resistor interposed between the positive supply plane and the output node; and,
a feedback circuit interposed between the input node and the output node, the feedback circuit for maintaining voltage drops across the input and the output resistors equal in order to mirror the input current to the output current.

31. A method for mirroring an input current I_in to an output current I_out comprising:
providing an input node for receiving the input current I_in;
providing an output node for providing the output current I_out;
providing an input resistor interposed between a positive supply plane and the input node;
providing an output resistor interposed between the positive supply plane and the output node;
providing a feedback circuit interposed between the input node and the output node; and,
mirroring the input current to the output current by maintaining voltage drops across the input and the output resistors equal using the feedback circuit.
